(19) United States
(12) Patent Application Publication
(10) Pub. No.: US 2026/0161856 A1
(43) Pub. Date: Jun. 11, 2026

(54) METHOD OF TIMING RESERVOIR GATE FOR SILTING REDUCTION BEFORE DAM

(71) Applicant: CHINA THREE GORGES CORPORATION, Wuhan, Hubei (CN)

(72) Inventors: Hanqing ZHAO, Wuhan, Hubei (CN); Chengxiao ZHANG, Wuhan, Hubei (CN); Huichao DAI, Wuhan, Hubei (CN); Dingguo JIANG, Beijing (CN); Boyu MI, Wuhan, Hubei (CN); Ran ZHAI, Wuhan, Hubei (CN); Xiufeng QUAN, Wuhan, Hubei (CN); Junjie RU, Wuhan, Hubei (CN)

(73) Assignee: CHINA THREE GORGES CORPORATION, Wuhan, Hubei (CN)

(21) Appl. No.: 18/706,006

(22) PCT Filed: Jun. 12, 2023
(86) PCT No.: PCT/CN2023/099738

§ 371 Date: Apr. 30, 2024

(30) Foreign Application Priority Data
Jul. 7, 2022 (CN) 202210794803.3

(51) Int. Cl. G06F 30/28; G06F 30/13

(52) U.S. Cl. CPC G06F 30/28; G06F 30/13

(57) ABSTRACT

A method of timing a reservoir gate for silting reduction before a dam is provided. The method comprises: giving an into-reservoir water-silting variation curve within a preset time-length in future; predicting an ante-dam water-silting variation curve at a preset section position before a dam based on the into-reservoir water-silting variation curve; using width parameters and water depth parameters of a river channel to refine the ante-dam water-silting variation curve; and performing simulation on a 3D water-silting movement process by means of the refined ante-dam water-silting variation curve and a plurality of preset gate opening plans, and based on a simulation result, selecting a gate opening plan involving least silting before the dam or most desilting reduction before the dam from the plurality of preset gate opening plans.

### FIELD

The present invention relates to the technical field of hydraulic engineering, specifically relates to a method of timing a reservoir gate for silting reduction before a dam.

### BACKGROUND

Retaining water in a reservoir will change a hydrodynamic situation of a river, resulting in siltation of silting coming from the upper reaches along the river and affecting flood protection, shipping safety and normal operation of a power station. At present, methods such as storing the clear and releasing the muddy, apportioning water and silting and adjusting a silting peak are generally adopted to apportion silting in a reservoir, that is, according to a situation about water and silting coming from the upper reaches, an ability for water flow to carry silting is exerted to discharge the silting out of the reservoir area as much as possible by way of controlling the opportunity of drainage from the dam and dynamically adjusting a discharge flow rate.

Silting mainly occurs in an area before a dam of a reservoir; thus, the serious siltation will threaten operational stability and structural safety of hydraulic buildings. However, a current silting-planning method mainly focuses on silting desilting in an entire reservoir area, and pays less attention to silting reduction before the dam. Specifically, a reservoir dam is equipped with a plurality of gates, and the current silting-planning method only stipulates a sum of discharge flow rates from the gates without concerning the extent to which each gate is opened, that is, there is no requirement for the combination of gate opening and the extent to which each gate is opened, as long as the sum of the discharge flow rates of the reservoir reaches requirements. However, the above two parameters, the combination of gate opening and the extent to which each gate is opened, have a crucial impact on the silting reduction before the dam. Therefore, how to further improve the effect of the silting reduction before the dam by way of optimizing and controlling a combination of opening-closing operations and opening extents of gate groups and under the premise of meeting the requirements of the sum of the discharge flow rates in the current silting-planning method is an urgent problem to be solved.

### SUMMARY

In view of the problem of siltation before the dam caused by ignoring a sequence of opening and closing gates in the current silting-planning method, the present invention provides a method of timing a reservoir gate for silting reduction before a dam, so as to further improve the effect of the silting reduction before the dam under the premise of meeting the requirements of the sum of the discharge flow rates in the current silting-planning method.

The present invention provides a method of timing a reservoir gate for silting reduction before a dam, comprising the steps of: giving an into-reservoir water-silting variation curve within a preset time-length in future, the into-reservoir water-silting variation curve including an into-reservoir flow-rate variation curve shows that an into-reservoir flow-rate varies with time, and an into-reservoir silting-content variation curve shows that an into-reservoir silting-content varies with time; predicting an ante-dam water-silting variation curve at a preset section position before a dam based on the into-reservoir water-silting variation curve; using width parameters and water depth parameters of a river channel to refine the ante-dam water-silting variation curve; and performing simulation on a 3D water-silting movement process by means of the refined ante-dam water-silting variation curve and a plurality of preset gate opening plans, and based on a simulation result, selecting a gate opening plan involving least silting before the dam or most desilting reduction before the dam from the plurality of preset gate opening plans.

Optionally, the step of predicting an ante-dam water-silting variation curve at a preset section position before a dam based on the into-reservoir water-silting variation curve includes the sub-steps of: predicting an out-reservoir flow-rate variation curve corresponding to the into-reservoir flow-rate variation curve by means of a reservoir-managing relation, which is used to present a corresponding relation between an into-reservoir flow and an out-reservoir flow at any moments; calculating a reservoir-area water-level variation curve based on the into-reservoir flow-rate variation curve and the out-reservoir flow-rate variation curve and in combination with a water level-reservoir capacity variation relation; inputting the into-reservoir flow-rate variation curve, the into-reservoir silting-content variation and the reservoir-area water-level variation curve into a preset one-dimensional water-silting movement model to calculate out an ante-dam flow-rate variation curve, an ante-dam water-level variation curve and an ante-dam silting-content variation curve at a preset position before the dam; calculating an ante-dam average flow velocity variation curve based on the ante-dam flow-rate variation curve and the ante-dam water-level variation curve; and using the ante-dam average flow velocity variation curve and the ante-dam silting-content variation curve as the ante-dam water-silting variation curve.

Optionally, the sub-step of predicting an out-reservoir flow-rate variation curve corresponding to the into-reservoir flow-rate variation curve by means of a reservoir-managing relation includes: inputting a corresponding into-reservoir flow-rate value of the into-reservoir flow-rate variation curve at each moment into the reservoir-managing relation to give a corresponding out-reservoir flow-rate value at each moment, and drawing and generating the out-reservoir flow-rate variation curve based on the corresponding out-reservoir flow-rate values at each moment; the reservoir-managing relation is that: before the into-reservoir flow-rate value rises to a flood peak, when the into-reservoir flow-rate value is less than a first preset threshold, the out-reservoir flow-rate value is equal to the into-reservoir flow-rate value; when the into-reservoir flow-rate value is not less than a first preset threshold, the out-reservoir flow-rate value is equal to the first preset threshold; after the into-reservoir flow-rate value starts to drop from a flood peak, when the into-reservoir flow-rate value is greater than a second preset threshold, the out-reservoir flow-rate value is equal to the into-reservoir flow-rate value; when the into-reservoir flow-rate value is not greater than a second preset threshold, the out-reservoir flow-rate value is equal to the second preset threshold.

Optionally, the sub-step of calculating a reservoir-area water-level variation curve based on the into-reservoir flow-rate variation curve and the out-reservoir flow-rate variation curve and in combination with a water level-reservoir capacity variation relation includes: obtaining the water level-reservoir capacity variation relation; calculating a reservoir capacity variation curve based on the into-reservoir flow-rate variation curve and the out-reservoir flow-rate variation curve; and inputting the reservoir capacity variation curve into the water level-reservoir capacity variation relation to calculate the reservoir-area water-level variation.

Optionally, the step of using width parameters and water depth parameters of a river channel to refine the ante-dam water-silting variation curve includes: obtaining the width parameters and the water depth parameters based on topography of the preset section position before the dam and the ante-dam water-level variation curve; in the case of keeping a flow velocity unchanged in a river width or water depth direction, performing differentiation on the width parameters or the water depth parameters based on the ante-dam average flow velocity variation curve to calculate an ante-dam average flow velocity variation curve corresponding to each water depth or an ante-dam average flow velocity variation curve corresponding to each river width; and in the case of keeping a silting-content unchanged in a river width or water depth direction, performing differentiation on the width parameters or the water depth parameters based on the ante-dam silting-content variation curve to calculate an ante-dam silting-content variation curve corresponding to each water depth or an ante-dam silting-content variation curve corresponding to each river width.

Optionally, a step of generating the plurality of preset gate opening plans includes: determining a position of an opened gate based on a height of a reservoir bed surface; and creating an opening plan of a gate corresponding to the position, so that the out-reservoir flow rate is equal to a sum of a total discharge flow rate and a full flow rate of a generator generating electric power at full capacity, and conforms to the reservoir-managing relation.

Optionally, the step of performing simulation on a 3D water-silting movement process by means of the refined ante-dam water-silting variation curve and a plurality of preset gate opening plans, and based on a simulation result, selecting a gate opening plan involving least silting before the dam or most desilting reduction before the dam from the plurality of preset gate opening plans, includes: obtaining a 3D model from the preset section position before the dam to a dam site and dividing the 3D model into grids; inputting the refined ante-dam water-silting variation curve into the 3D model divided into grids to give a 3D water-silting movement model; using the 3D water-silting movement model to ergodically simulate each preset gate opening plan, and recording a silting-volume inlet-outlet difference value corresponding to each preset gate opening plan, and using a gate opening plan having a minimum silting-volume inlet-outlet difference value as the gate opening plan involving least silting before the dam or most desilting reduction before the dam.

The technical solution provided by the present invention has the following advantages:

In the technical solution provided in the present invention, an into-reservoir flow rate and a silting-content at the inlet of the reservoir in a preset time-length in future are collected to form a curve relation that varies with time, respectively, so as to give an into-reservoir water-silting variation curve. Then, the into-reservoir water-silting variation curve is used to perform one-dimensional water-silting movement simulation, so as to calculate a water-silting variation curve at a position before the dam (that is, a relation of a flow rate, a silting-content and a flow velocity at any position of the preset section before the dam that vary with time). Since the one-dimensional water-silting simulation has high computational efficiency and few requirements for data, and the scope of the entire reservoir area is large, the one-dimensional water-silting simulation (that is, only make a calculation on a temporal variation process of water and silting in a flow direction) is used to give a preliminary ante-dam water-silting variation curve. Then, a river width and a water depth as two-dimension parameters are introduced into the ante-dam water-silting variation curve and refined, so as to give a 3D ante-dam water-silting variation curve in any width and water depth direction of the preset section in different time-lengths, thereby improving the accuracy of the variation curve. Then, a 3D water-silting movement model is established by using the refined ante-dam water-silting variation curve, so as to simulate water-silting movement in line of different gate opening plans, then record the situations about silting reduction before the dam corresponding to different gate opening plans, thus select a gate opening plan involving least silting before the dam or most desilting reduction before the dam from the plurality of preset gate opening plans. In this way, the optimized gate timing tactic enables silting reduction before the dam to improve.

### BRIEF DESCRIPTION OF THE DRAWINGS

The features and advantages of the present invention will be more clearly understood by referring to the drawings, which are schematic and should not be construed as imposing any limitation on the invention, in the drawings:

FIG. 1 is a diagram showing the steps of the method of timing a reservoir gate in one embodiment of the present invention.

FIG. 2 is a diagram of showing changes of flood flow in the prior art.

FIG. 3 is a diagram showing the scope of one-dimensional water-silting simulation in one embodiment of the present invention.

FIG. 4 is a diagram showing the flow rate changes coming into a reservoir in future in one embodiment of the present invention.

FIG. 5 is a diagram showing the silting-content changes coming into a reservoir in future in one embodiment of the present invention.

FIG. 6 is a diagram showing the water-level changes before a dam in one embodiment of the present invention.

FIG. 7 is a diagram showing the flow rate changes of the preset section before a dam in one embodiment of the present invention.

FIG. 8 is a diagram showing the silting-content changes of the preset section before a dam in one embodiment of the present invention.

FIG. 9 is a diagram showing the topography and gate layout of the preset section before a dam in one embodiment of the present invention.

FIG. 10 is a diagram showing the grid pattern of the 3D model for a reservoir in one embodiment of the present invention.

### DETAILED DESCRIPTION

In order to make the objective, the technical solution and the advantage of the examples of the present invention clearer, we shall clearly and completely describe the technical solution in the examples of the present invention in combination with the following drawings in the examples, it is obvious that the described example is part of the embodiments of the present invention, not all of the embodiments. Based on the examples of the present invention, all other examples obtained by a person skilled in the art without creative efforts shall fall within the protection scope of the present invention.

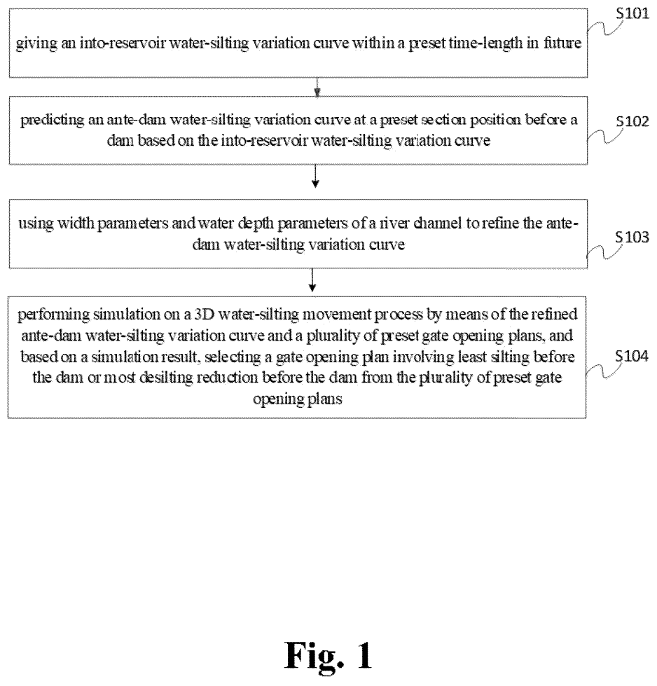

As shown in FIG. 1, in one embodiment, a method of timing a reservoir gate for silting reduction before a dam includes the steps of:

S101: giving an into-reservoir water-silting variation curve within a preset time-length in future, wherein the into-reservoir water-silting variation curve includes an into-reservoir flow-rate variation curve shows that an into-reservoir flow-rate varies with time, and an into-reservoir silting-content variation curve shows that an into-reservoir silting-content varies with time.

S102: predicting an ante-dam water-silting variation curve at a preset section position before a dam based on the into-reservoir water-silting variation curve.

S103: using width parameters and water depth parameters of a river channel to refine the ante-dam water-silting variation curve.

S104: performing simulation on a 3D water-silting movement process by means of the refined ante-dam water-silting variation curve and a plurality of preset gate opening plans, and based on a simulation result, selecting a gate opening plan involving least silting before the dam or most desilting reduction before the dam from the plurality of preset gate opening plans.

Specifically, in this example, adjusting the different openings of the reservoir gates in the proposed method of timing a reservoir gate indirectly affects the movement of water and silting, and achieves the purpose of reducing silting before the dam without changing a sum of discharge flow rates. In order to achieve this purpose, in this example, firstly obtaining a variation relation (that is a water-silting variation curve) between an into-reservoir flow rate and a silting-content in a preset time-length in future that vary with time according hydrological data; then according to the obtained water-silting variation curve, performing one-dimensional simulation on water-silting movement that only puts a water-silting variation process in a flow direction into account, so as to quickly predict a variation relation between a flow rate and a silting-content at a preset position before the dam, thus giving an ante-dam water-silting variation curve (assuming that a total length of a reservoir is 600 km, an into-reservoir position is 600 km away from a dam, and a preset section before the dam is not far from the upper reaches of the dam, for example, 15 km away from the dam.). Based on this, bringing a river width and a water depth as two-dimension parameters into the ante-dam water-silting variation curve and refining its accuracy, so as to prepare for subsequent 3D simulation on water-silting movement. Then, creating a plurality of gate opening plans in advance and a 3D model of the river segment of the dam site, then inputting the refined ante-dam water-silting variation curve into the 3D model, thus performing 3D simulation on water-silting movement one by one according to the plurality of preset gate opening plans, then recording the situations about siltation before the dam corresponding to each gate opening plan, thus selecting a gate opening plan involving least silting before the dam or most desilting reduction before the dam from the plurality of preset gate opening plans, so as to realize optimally timing gates.

In this example, the specific process of obtaining a variation relation between an into-reservoir flow rate and a silting-content in a preset time-length in future that vary with time includes the steps of collecting data about coming water and coming silting from each tributary in a reservoir area in future, and then superimposing process curves of coming water and coming silting from each tributary in the reservoir area in future, so as to calculate out a total process of into-reservoir water and silting.

Specifically, in one embodiment, in S102, includes the steps of:
S1: predicting an out-reservoir flow-rate variation curve corresponding to the into-reservoir flow-rate variation curve by means of a reservoir-managing relation, which is used to present a corresponding relation between an into-reservoir flow and an out-reservoir flow at any moments.
S2: calculating a reservoir-area water-level variation curve based on the into-reservoir flow-rate variation curve and the out-reservoir flow-rate variation curve and in combination with a water level-reservoir capacity variation relation.
S3: inputting the into-reservoir flow-rate variation curve, the into-reservoir silting-content variation and the reservoir-area water-level variation curve into a preset one-dimensional water-silting movement model to calculate out an ante-dam flow-rate variation curve, an ante-dam water-level variation curve and an ante-dam silting-content variation curve at a preset position before the dam.
S4: calculating an ante-dam average flow velocity variation curve based on the ante-dam flow-rate variation curve and the ante-dam water-level variation curve.
S5: using the ante-dam average flow velocity variation curve and the ante-dam silting-content variation curve as the ante-dam water-silting variation curve.

Specifically, in this example, on the basis of the one-dimensional water-silting simulation, an output of the one-dimensional water-silting simulation is used as an input parameter of the 3D water-silting simulation, so as to achieve an accurate 3D water-silting simulation. In order to perform 3D water-silting simulation, it is necessary to obtain a variation relation of average flow velocity before the dam with time and a variation relation of silting-contents before the dam with time through the one-dimensional water-silting simulation. Based on this, in this example, firstly determining a variation process of out-reservoir flow rates with time, that is, an out-reservoir flow-rate variation curve Qₒᵤₜ₋ₜ, according to the into-reservoir flow-rate variation curve Q_{in˜t} and in combination with a reservoir-managing relation (the reservoir-managing relation specifies a specific into-reservoir flow rate corresponding to a specific out-reservoir flow rate at any time). Then, performing function analysis on Qₒᵤₜ₋ₜ, Qᵢₙ₋ₜ and reservoir capacity to give a variation process of water levels in the reservoir area that vary with time, that is, a reservoir-area water-level variation curve Z_{˜t}. Then, performing one-dimensional simulation on water and silting for the whole river segment of the reservoir area (only putting a water-silting variation process in a flow direction into account): using Qᵢₙ₋ₜ, a reservoir-area water-level variation curve Z_{˜t}, and an into-reservoir silting-content variation curve as input conditions of the model, then making a hydrodynamic solution by means of a finite difference method and making a silting solution by means of an explicit method in combination with on-way changes of river roughness with water levels, so as to give a dynamic variation process of flow rates, silting-contents and water levels at any section position in the reservoir area. Further, for the preset position section of the river segment before the dam (that is, a section located at 15 km upstream of the dam site in this example), extracting calculation data of flow rates, water levels and silting-contents over the next month to give a water-silting process of the inlet section corresponding to the river segment before the dam, that is, an ante-dam flow-rate variation curve, an ante-dam water-level variation curve and an ante-dam silting-content variation curve.

In the subsequent 3D simulation, the input parameters required for the 3D model includes flow velocity variables that vary with river widths, water depths and river directions, so it is also necessary to calculate a flow velocity-time variation relation of water and silting in a river direction through the ante-dam flow-rate variation curve and the ante-dam water-level variation curve, that is, an ante-dam average flow velocity variation curve, so as to give a subsequent 3D flow velocity relation. The specific method is as follows: giving a variation process of the average flow velocity Uₘ at the section and the average silting-content Sₘ at the section in a preset time length in future, in combination with the water level variation curve of the dam site and the topography of the preset section before the dam; finally, giving a variation curve of flow velocity U and silting-contents S that vary with time at any position corresponding to the preset section, in combination with a variation curve of river width parameters and water depth parameters that vary with time corresponding to the preset section before the dam.

Specifically, in one embodiment, in S1, includes the steps of:
S6: inputting a corresponding into-reservoir flow-rate value of the into-reservoir flow-rate variation curve at each moment into the reservoir-managing relation to give a corresponding out-reservoir flow-rate value at each moment, and drawing and generating the out-reservoir flow-rate variation curve based on the corresponding out-reservoir flow-rate values at each moment.

The reservoir-managing relation is that: before the into-reservoir flow-rate value rises to a flood peak, when the into-reservoir flow-rate value is less than a first preset threshold, the out-reservoir flow-rate value is equal to the into-reservoir flow-rate value; when the into-reservoir flow-rate value is not less than a first preset threshold, the out-reservoir flow-rate value is equal to the first preset threshold; after the into-reservoir flow-rate value starts to drop from a flood peak, when the into-reservoir flow-rate value is greater than a second preset threshold, the out-reservoir flow-rate value is equal to the into-reservoir flow-rate value; when the into-reservoir flow-rate value is not greater than a second preset threshold, the out-reservoir flow-rate value is equal to the second preset threshold.

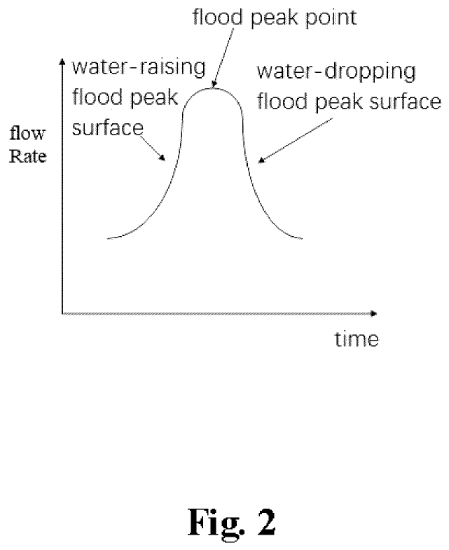

Specifically, giving an into-reservoir flow-rate value corresponding to each moment of the into-reservoir flow-rate variation curve, then outputting a corresponding out-reservoir flow-rate value according to a mapping relation (a reservoir-managing relation) in one-to-one correspondence between the into-reservoir flow-rate and the out-reservoir flow-rate, that is, drawing out an out-reservoir flow-rate curve. In this example, the reservoir-managing relation adopts a tactic called “on a water-raising flood peak surface, store water and block silting; on a water-dropping flood peak surface, boost discharge amount and flush away silting”, so as to perform desilting; FIG. 2 shows a variation process of flood flow rates with time in certain flood progress. Thus, the tactic “on a water-raising flood peak surface, store water and block silting; on a water-dropping flood peak surface, boost discharge amount and flush away silting” includes the steps of in the course of the water-raising flood peak surface, enabling the reservoir to store water and intercept a part of the silting, and in the course of the water-dropping flood peak surface, enabling the reservoir to boost discharge amount, flush away silting in the reservoir area and discharge it from the reservoir, so as to improve the effect of desilting reduction before the dam.

A specific example is taken to explain the tactic as follows.

On a water-raising flood peak surface (before the into-reservoir flow-rate value rises to the flood peak), when the into-reservoir flow-rate value is less than 30,000 m³/s (a first preset threshold), releasing floodwater according to an actual into-reservoir flow-rate value, that is, Qₒᵤₜ=Qᵢₙ; otherwise, releasing floodwater according to 30,000 m³/s, that is, Qₒᵤₜ-30,000 m³/s (a first preset threshold). On a water-dropping flood peak surface (after the into-reservoir flow-rate value starts to drop from the flood peak), when the into-reservoir flow-rate value is greater than 40,000 m³/s (a second preset threshold), releasing floodwater according to an actual into-reservoir flow-rate value, that is, Qₒᵤₜ=Qᵢₙ; otherwise, releasing floodwater according to 40,000 m³/s, that is, Qₒᵤₜ=40,000 m³/s. According to the above reservoir-managing relation, it is possible to correspondingly give a variation process of the out-reservoir flow-rate value Qₒᵤₜ with time t.

Specifically, in one embodiment, in S2, includes the steps of:
S7: obtaining the water level-reservoir capacity variation relation.
S8: calculating a reservoir capacity variation curve based on the into-reservoir flow-rate variation curve and the out-reservoir flow-rate variation curve.
S9: inputting the reservoir capacity variation curve into the water level-reservoir capacity variation relation to calculate the reservoir-area water-level variation.

Specifically, when a relation between the reservoir capacity V and the reservoir water level Z conforms to Z=41V^{0.24}, solving the problem about inflow and outflow in combination with the current water level, reservoir capacity and relation between Qᵢₙ₋ₜ, and Qₒᵤₜ₋ₜ, that is, it is possible to predict a variation process Z˜t of the water levels in the reservoir area that vary with time in a preset time length in future.

Specifically, in one embodiment, in S103, includes the steps of:
S10: in the case of keeping a flow velocity unchanged in a river width or water depth direction, performing differentiation on the width parameters or the water depth parameters based on the ante-dam average flow velocity variation curve to calculate an ante-dam average flow velocity variation curve corresponding to each water depth or an ante-dam average flow velocity variation curve corresponding to each river width.
S11: in the case of keeping a silting-content unchanged in a river width or water depth direction, performing differentiation on the width parameters or the water depth parameters based on the ante-dam silting-content variation curve to calculate an ante-dam silting-content variation curve corresponding to each water depth or an ante-dam silting-content variation curve corresponding to each river width.

Specifically, what is given from the one-dimensional water-silting model is average values at a section, that is, an average water flow velocity Uₘ and an average silting-content Sₘ. In an actual application scenario, as the flow-rate continuously changes, the water level constantly changes, the water level change will lead to the continuous change of water depths and river widths in combination with the actual topography of the river channel; therefore, provided that it needs to give an accurate simulation process of water-silting movement, it is necessary to know the flow velocities U and the silting-content S corresponding to different water depths and different river widths. Firstly, analyzing the ante-dam water level variation curve in combination with topography of a preset section before the dam to obtain a width parameter and a water depth parameter of the river channel, as well as a variation process of the average flow velocity Uₘ and the average silting-content Sₘ at the section in a preset time length in future. Then, assuming that the water-silting movement along the river width remains unchanged, calculating a variation curve of the flow velocity and the silting-content of the section corresponding to any water depth position that vary with time in combination with a distribution formula of water and silting along the water depth and a variation curve of Uₘ and Sₘ.

Specifically, assuming that the flow velocity U is constant along the river width and distributed logarithmically along the water depth, it conforms to the following formula.

$$U = \frac{1}{κ} ln z + C$$

$${\int }_{0}^{h} Udz / h = {U}_{m}$$

Where, z represents a height upwards from a riverbed; U represents a flow velocity at height z; Uₘ represents an average flow velocity before a dam, which can be obtained from the ante-dam average flow velocity variation curve; κ is a constant, κ=0.4, C is a constant, h represents a water depth, that is, a difference value between a water level Z and a riverbed altitude. Therefore, by solving a differential of the above formula, it is possible to obtain the flow velocity value U at any water depth position of the inlet section in a preset time length in future.

In the same way, assuming that the flow velocity remains unchanged along the water depth, creating an integral relation between the river width and the flow velocity, so as to give a value of the flow velocity U before the dam at any river width position in a preset time length in future through differentiation, but the specific formula will not be repeated.

Then, assuming that the silting-content S of the water body remains unchanged along the river width and is distributed along the water depth according to the Rouse formula, it conforms to the following formula.

$$\frac{S}{{S}_{a}} = {( \frac{h - z}{z} \frac{a}{h - a} )}^{ω / ( κ {U}_{*} )}$$

$${\int }_{0}^{h} Sdz / h = {S}_{m}$$

Where, S represents a silting-content of a water body at height z; Sa represents a silting-content of a water body at height z=a; ω represents a silting velocity, conforming to

$$ω = {[ {( 13.95 \frac{v}{d} )}^{2} + 1.09 \frac{{γ}_{s} - γ}{γ} gd ]}^{1 / 2} - 13.95 \frac{v}{d} ,$$

wherein ν represents a viscosity coefficient of water flow, d represents a particle size of silting, γₛ and γ represent volume-weights of silting and water, respectively, and U* represents a friction velocity. Thus, by solving a differential of formula, it is possible to obtain a change value of the silting-content S of the water body before the dam at any water depth position of the inlet section over the next month.

How to calculate the silting-content S of the water body before the dam at any river width position in a preset time length in future is same with the above formula, so its specific formula will not be repeated herein.

Through the above S10 to S11, it is possible to achieve refining the ante-dam water-silting variation curve based on the river width parameter and the water depth parameter, meanwhile converting calculation results of the one-dimensional model into input conditions needed to be calculated by the 3D model, so as to get ready for the subsequent 3D water-silting simulation.

Specifically, in one embodiment, a step of generating the plurality of preset gate opening plans comprises:
S12: determining a position of an opened gate based on a height of a reservoir bed surface.
S13: creating an opening plan of a gate corresponding to the position, so that the out-reservoir flow rate is equal to a sum of a total discharge flow rate and a full flow rate of a generator generating electric power at full capacity, and conforms to the reservoir-managing relation.

Specifically, in this example, the obtained situations about siltation before the dam include a silting thickness, and particle size composition and hardening conditions of silting and variations of the above-mentioned factors along the river width; as they are intuitively reflected as height of a reservoir bed, based on this it is possible to determine a number of gates that need to be opened for planning silting reduction; the higher the bed height, the more the presented silting, and the gate at the corresponding position needs to be opened preferentially. Then, a discharge capacity formula for gates is used to calculate the discharge flow rate of the i^{th} gate Qᵢ=μBᵢeᵢ\sqrt{2gHᵢ}. Where, μ=0.87, Bᵢ represents a gate width, eᵢ represents a relative height of an opened gate, g represents gravitational acceleration, and Hᵢ represents a difference value between a water level of a dam site and an altitude of a gate baseplate. A plan for opening and closing a number of groups of gates is designed in advance, according to the dynamic change of the water level in the reservoir area, that is, a Z˜t relation, under the premise of conforming to

$${\sum }_{i = 1}^{N} {Q}_{i} = {Q}_{out} - {Q}_{machine}$$

(that is, the out-reservoir flow rate is composed of two parts, including a total gate discharge flow rate and a full flow rate of a generator generating electric power at full capacity, the gate and the generator are located in different channels, and the flow rate of the generator channel through which no silting passes is only used for power generation.), wherein, N represents a total number of gates, and Q_{machine} represents a full flow rate of a generator set, and in combination with the gate determined to be opened preferentially. Theoretically, the pre-created plan has a certain silting reduction effect on the silting before the dam, that is, several F(e₁, e₂, . . . eᵢ . . . e_{N})˜t relations, which represent the opening of each gate at different moments t, reflecting a dynamic operating process of the gates. Thus, on this basis, carrying out the optimization of timing gates saves the time for solving an optimal gate timing plan.

Specifically, in one embodiment, in S104, includes the steps of:

S14: obtaining a 3D model from the preset section position before the dam to a dam site and dividing the 3D model into grids.

S15: inputting the refined ante-dam water-silting variation curve into the 3D model divided into grids to give a 3D water-silting movement model.

S16: using the 3D water-silting movement model to ergodically simulate each preset gate opening plan, and recording a silting-volume inlet-outlet difference value corresponding to each preset gate opening plan.

S17: using a gate opening plan having a minimum silting-volume inlet-outlet difference value as the gate opening plan involving least silting before the dam or most desilting reduction before the dam.

Specifically, performing 3D modeling on a river segment and a dam body before the dam, wherein the dam body is set as a water blocking wall composed of a plurality of gates, and the number and position of the gates correspond to the actual situation, and the opening of the gates is set according to F(e₁, e₂, . . . eᵢ . . . e_{N})˜t relations; making grid divisions and performing water-silting simulation according to topographic data, wherein making grid divisions is a necessary step for the 3D water-silting simulation, because the 3D simulation is to calculate changes of water-silting movement in three directions, in a specific calculation process, it is necessary to divide into many different small grids, thus making a calculation on water-silting data of different grids gives changes of water-silting movement in three directions; then, giving a difference value between volumes of silting at an inlet and an outlet in the model and river topography data before the dam after planning silting reduction, and reflecting a silting reduction effect before the dam by means of the difference value between volumes of silting at an inlet and an outlet. In this way, performing the above-mentioned 3D water-silting simulation on each gate opening plan enables an optimal gate opening plan and improves a silting reduction effect before the dam.

A specific scenario is taken as an instance as follows, so as to describe the method of timing a reservoir gate provided in the example of the present invention.

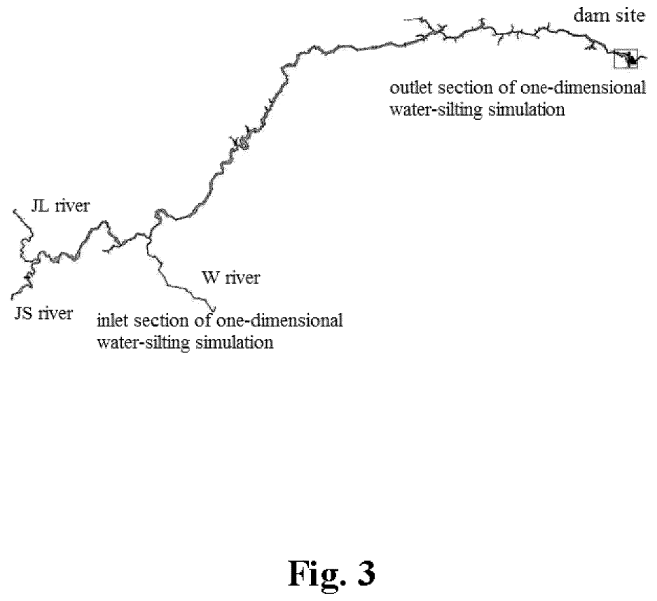

A timing mode for a river-type reservoir is taken as an instance. The total length of the trunk stream of the river-type reservoir area is 660 km, and the length of the river segment before the dam is 15 km. As shown in FIG. 3, there are many tributaries in the reservoir area, but the water and silting mainly come from the JS, JL and W rivers. Power generation runs through water diversion, and a full flow rate of the generator set is Q=10000 m³/s. The dam body is provided with 17 flood discharge holes (that is, the number of gates N=17), and the volume of discharge flow is controlled by means of a flat gate, which is 30 m high, Bi=20 m wide, and an altitude of a gate baseplate is loom.

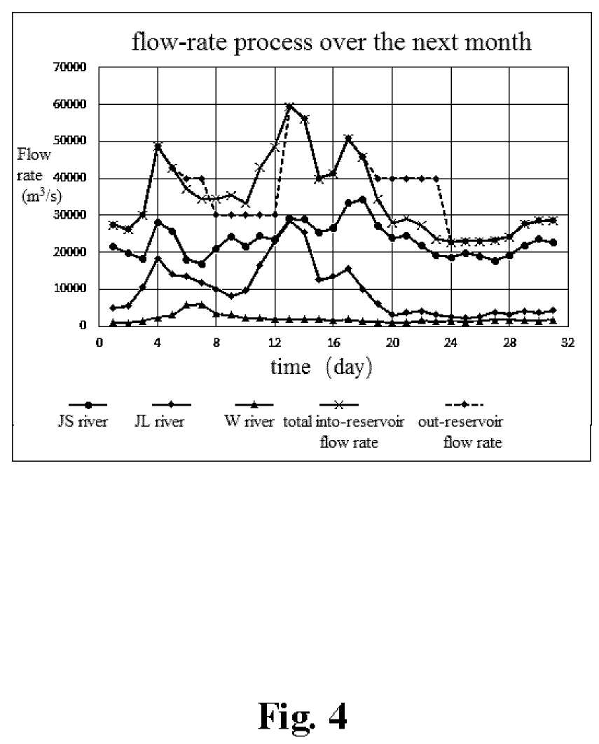

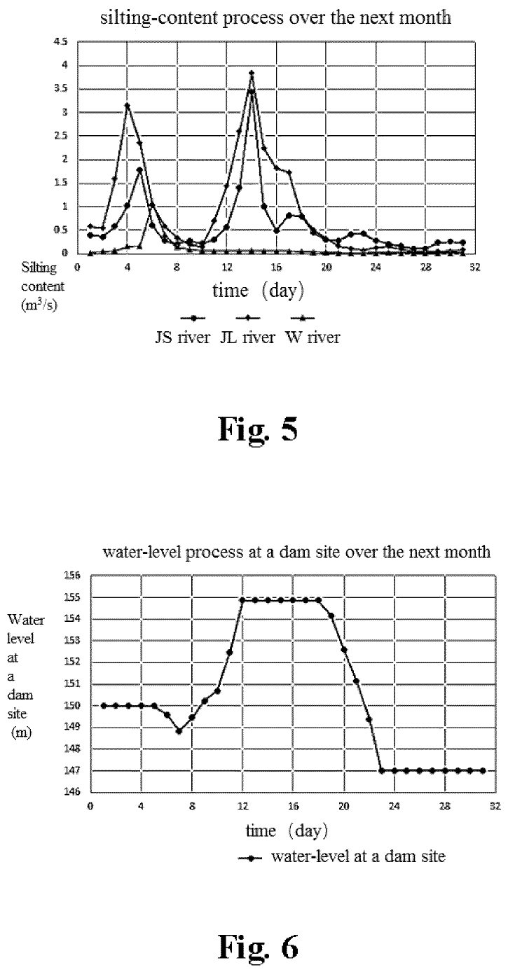

Firstly, calculating a variation process Q_{in ˜4} of the total into-reservoir flow rate that varies with time. At present, the water level of the reservoir dam site reaches Z=150 m, and the storage capacity reaches V=22.239 billion m³. It is known that over the next month, the flow-rate and the silting-content processes of the JS, JL, and W rivers are shown in FIG. 4 and FIG. 5, respectively. On this basis, the variation process Q_{in˜t} of the total into-reservoir flow rate that varies with time is given as shown in FIG. 4.

Then, calculating a variation process Q_{out˜t} of out-reservoir flow rates with time, the reservoir-managing relation adopts a tactic called “on a water-raising flood peak surface, store water and block silting, on a water-dropping flood peak surface, boost discharge amount and flush away silting”, so as to perform desilting; giving a variation process of out-reservoir flow rates Qₒᵤₜ with time t, as shown in FIG. 4.

Then, determining a variation process Z_{˜t} of water levels in the reservoir area that vary with time; when a relation between the reservoir capacity V and the reservoir water level Z conforms to Z=41V^{0.24}, predicting a variation process Z˜t of the water levels in the reservoir area that vary with time in a preset time length in future in combination with the current water level, the reservoir capacity and the relation between Q_{in˜t}, and Q_{out˜t}, wherein the corresponding results are shown in FIG. 6.

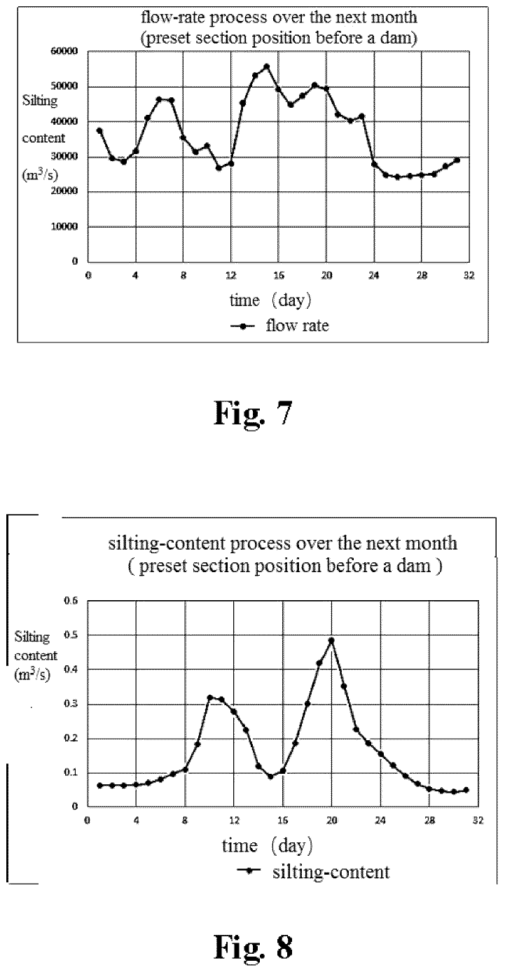

Then, performing one-dimensional simulation on water and silting for the whole river segment of the reservoir area, using Q_{in˜t}, a reservoir-area water-level variation curve Z_{˜t}, and an into-reservoir silting-content variation curve as input conditions of the model to give a water-silting process of the river segment before the dam. Specifically, modeling based on the connection relation between the tributaries and the cross-sectional topography of the reservoir area; using the variation processes of the flow and the silting-content of the JS, JL and W rivers varying with time and the Z˜t relation of the dam site as input conditions of the model, then making a hydrodynamic solution by means of a finite difference method and making a silting solution by means of an explicit method in combination with on-way changes of river roughness with water levels, so as to give a dynamic variation process of flow rates, silting-contents and water levels at any section position in the reservoir area. Further, for the inlet section of the river segment before the dam (that is, a section located at 15 km upstream of the dam site), extracting calculation data of flow rates, water levels and silting-contents over the next month as shown in FIGS. 7-8.

Then, using the river width parameter and the water depth parameter to refine the variation curves in FIGS. 7-8, giving an ante-dam flow velocity variation relation corresponding to each water depth, an ante-dam flow velocity variation relation corresponding to each river channel width, an ante-dam silting-content variation relation corresponding to each water depth and an ante-dam silting-content variation relationship corresponding to each river channel width.

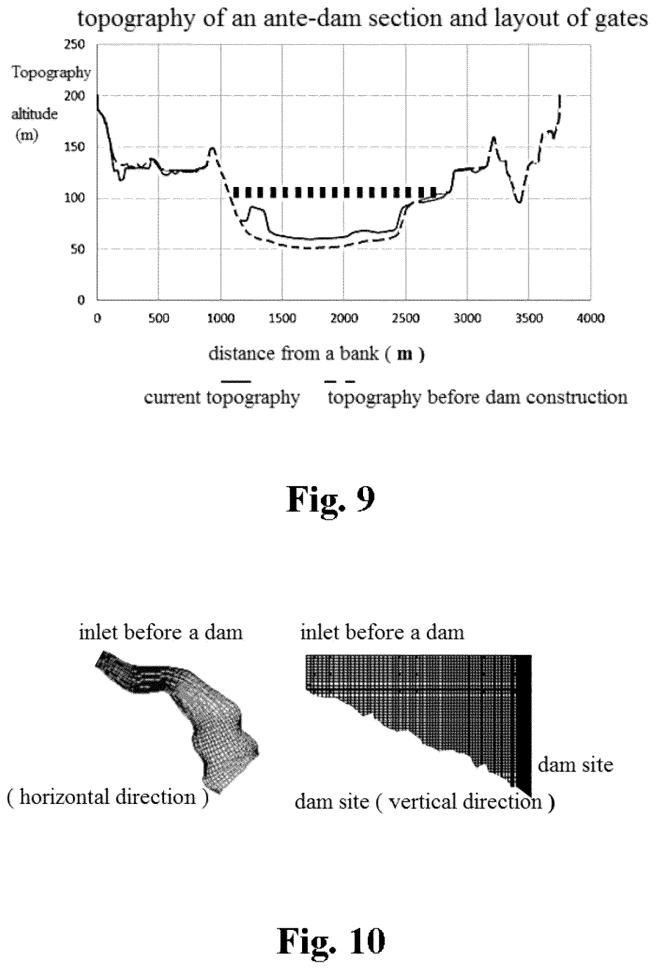

Then, creating a plurality of gate opening plans in advance: designing several groups of plans for opening and closing gates in combination with the discharge process through the gates over the next month and the key portion of silting reduction before the dam. Specifically, investigating the situations about siltation before the dam, which include a silting thickness, and particle size composition and hardening conditions of silting and variations of the above-mentioned factors along the river width, in combination with the hydrological observation data and dam design data, as shown in FIG. 9. Among them, the black squares represent gates, which are defined as Gate 1 #, Gate 2 # . . . , and Gate 17 #, from left to right. It can be seen from FIG. 9 that the altitudes of the river bed surfaces corresponding to Gates15-17 # are larger, but the silting since having constructed the reservoir is not significant, and the riverbed is mainly composed of large-scale rocks, which are not suitable for planning silting reduction. In contrast, the situation of silting corresponding to Gates 2-3 # is more significant. Therefore, at the time of planning silting reduction before the dam, Gates 2-3 # should be opened preferentially. According to the discharge capacity formula for gates, the discharge flow rate of the i^{th} gate Qᵢ conforms to Qᵢ=μBᵢeᵢ\sqrt{2gHᵢ}. Where, μ=0.87, Bᵢ represents a gate width, Bᵢ=20 m; eᵢ represents a relative height of an opened gate; g=10 m/s²; and Hᵢ represents a difference value between a water level of a dam site and an altitude of a gate baseplate, Hᵢ=Z−100 m. At any moments, the sum of the discharge flow rate of all gates is equal to a difference value between the out-reservoir flow rate Qₒᵤₜ and the full flow rate Q_{machine} of the generator generating electric power at full capacity. That is, it conforms to the following formula.

$${\sum }_{i = 1}^{17} 17.4 {e}_{i} \sqrt{20 ( Z - 100 )} = {Q}_{out} - 10000$$

In most cases, the sum of the discharge flow rates corresponding to the full opening of Gates 2 #-3 # is greater than “Qₒᵤₜ−10000”. In this example, several groups of plans for opening and closing gates are designed as follows.

Plan 1: Giving a priority that ensures that Gate 2 # is fully open, and the insufficient flow rate is made up through Gate 3 #, then further considering the opening of Gates 1-4 #.

Plan 2: Giving a priority that ensures that Gate 3 # is fully open, and the insufficient flow rate is made up through Gate 2 #, then further considering the opening of Gates 1-4#.

Plan 3: Ensuring that Gates 2 #-3 #gates always maintain opening to the same extent.

The dynamic changes of the gate opening (unit: m) corresponding to each plan are shown in Table 1.

TABLE 1
Gate opening plan table

| | Plan 1 | | | | Plan 2 | | | | Paln3 | | | |
|---|---|---|---|---|---|---|---|---|---|---|---|---|
| Days | 1# | 2# | 3# | 4# | 1# | 2# | 3# | 4# | 1# | 2# | 3# | 4# |
| 1 | 0.00 | 30.00 | 1.84 | 0.00 | 0.00 | 1.84 | 30.00 | 0.00 | 0.00 | 15.92 | 15.92 | 0.00 |
| 2 | 0.00 | 29.36 | 0.00 | 0.00 | 0.00 | 0.00 | 29.36 | 0.00 | 0.00 | 14.68 | 14.68 | 0.00 |
| 3 | 0.00 | 30.00 | 6.75 | 0.00 | 0.00 | 6.75 | 30.00 | 0.00 | 0.00 | 18.37 | 18.37 | 0.00 |
| 4 | 10.39 | 30.00 | 30.00 | 10.39 | 10.39 | 30.00 | 30.00 | 10.39 | 10.39 | 30.00 | 30.00 | 10.39 |
| 5 | 0.00 | 30.00 | 29.70 | 0.00 | 0.00 | 29.70 | 30.00 | 0.00 | 0.00 | 29.85 | 29.85 | 0.00 |
| 6 | 0.00 | 30.00 | 24.74 | 0.00 | 0.00 | 24.74 | 30.00 | 0.00 | 0.00 | 27.37 | 27.37 | 0.00 |
| 7 | 0.00 | 30.00 | 25.18 | 0.00 | 0.00 | 25.18 | 30.00 | 0.00 | 0.00 | 27.59 | 27.59 | 0.00 |
| 8 | 0.00 | 30.00 | 6.55 | 0.00 | 0.00 | 6.55 | 30.00 | 0.00 | 0.00 | 18.27 | 18.27 | 0.00 |
| 9 | 0.00 | 30.00 | 6.26 | 0.00 | 0.00 | 6.26 | 30.00 | 0.00 | 0.00 | 18.13 | 18.13 | 0.00 |
| 10 | 0.00 | 30.00 | 6.10 | 0.00 | 0.00 | 6.10 | 30.00 | 0.00 | 0.00 | 18.05 | 18.05 | 0.00 |
| 11 | 0.00 | 30.00 | 5.48 | 0.00 | 0.00 | 5.48 | 30.00 | 0.00 | 0.00 | 17.74 | 17.74 | 0.00 |
| 12 | 0.00 | 30.00 | 4.70 | 0.00 | 0.00 | 4.70 | 30.00 | 0.00 | 0.00 | 17.35 | 17.35 | 0.00 |
| 13 | 25.96 | 30.00 | 30.00 | 25.96 | 25.96 | 30.00 | 30.00 | 25.96 | 25.96 | 30.00 | 30.00 | 25.96 |
| 14 | 20.27 | 30.00 | 30.00 | 20.27 | 20.27 | 30.00 | 30.00 | 20.27 | 20.27 | 30.00 | 30.00 | 20.27 |
| 15 | 0.00 | 30.00 | 22.05 | 0.00 | 0.00 | 22.05 | 30.00 | 0.00 | 0.00 | 26.02 | 26.02 | 0.00 |
| 16 | 0.00 | 30.00 | 24.63 | 0.00 | 0.00 | 24.63 | 30.00 | 0.00 | 0.00 | 27.32 | 27.32 | 0.00 |
| 17 | 10.84 | 30.00 | 30.00 | 10.84 | 10.84 | 30.00 | 30.00 | 10.84 | 10.84 | 30.00 | 30.00 | 10.84 |
| 18 | 1.94 | 30.00 | 30.00 | 1.94 | 1.94 | 30.00 | 30.00 | 1.94 | 1.94 | 30.00 | 30.00 | 1.94 |
| 19 | 0.00 | 30.00 | 22.38 | 0.00 | 0.00 | 22.38 | 30.00 | 0.00 | 0.00 | 26.19 | 26.19 | 0.00 |
| 20 | 0.00 | 30.00 | 23.16 | 0.00 | 0.00 | 23.16 | 30.00 | 0.00 | 0.00 | 26.58 | 26.58 | 0.00 |
| 21 | 0.00 | 30.00 | 23.91 | 0.00 | 0.00 | 23.91 | 30.00 | 0.00 | 0.00 | 26.96 | 26.96 | 0.00 |
| 22 | 0.00 | 30.00 | 24.86 | 0.00 | 0.00 | 24.86 | 30.00 | 0.00 | 0.00 | 27.43 | 27.43 | 0.00 |
| 23 | 0.00 | 30.00 | 26.23 | 0.00 | 0.00 | 26.23 | 30.00 | 0.00 | 0.00 | 28.12 | 28.12 | 0.00 |
| 24 | 0.00 | 23.94 | 0.00 | 0.00 | 0.00 | 0.00 | 23.94 | 0.00 | 0.00 | 11.97 | 11.97 | 0.00 |
| 25 | 0.00 | 24.57 | 0.00 | 0.00 | 0.00 | 0.00 | 24.57 | 0.00 | 0.00 | 12.29 | 12.29 | 0.00 |
| 26 | 0.00 | 24.42 | 0.00 | 0.00 | 0.00 | 0.00 | 24.42 | 0.00 | 0.00 | 12.21 | 12.21 | 0.00 |
| 27 | 0.00 | 25.21 | 0.00 | 0.00 | 0.00 | 0.00 | 25.21 | 0.00 | 0.00 | 12.61 | 12.61 | 0.00 |
| 28 | 0.00 | 26.67 | 0.00 | 0.00 | 0.00 | 0.00 | 26.67 | 0.00 | 0.00 | 13.34 | 13.34 | 0.00 |
| 29 | 0.00 | 30.00 | 3.22 | 0.00 | 0.00 | 3.22 | 30.00 | 0.00 | 0.00 | 16.61 | 16.61 | 0.00 |
| 30 | 0.00 | 30.00 | 4.86 | 0.00 | 0.00 | 4.86 | 30.00 | 0.00 | 0.00 | 17.43 | 17.43 | 0.00 |
| 31 | 0.00 | 30.00 | 4.96 | 0.00 | 0.00 | 4.96 | 30.00 | 0.00 | 0.00 | 17.48 | 17.48 | 0.00 |

Then, performing 3D simulation on the water and silting before the dam to analyze the situations about water and silting at the inlet section of the river segment before the dam at any time and at any spatial positions, so as to estimate a silting reduction effect: making grid divisions and performing water-silting simulation on the area to be researched through 3D water-silting simulation, that is, the position of the outlet section in FIG. 3, in combination with the topographic data of the 3D river section and the opening and closing of Gates 1 #-44 #. The 3D area horizontally includes orthogonal curve grids, which are divided into 90 layers in the vertical direction; the horizontal and vertical grids are shown in FIG. 10, and the gate is arranged in the area below the 45th layer of the vertical grids. In addition, performing grid encryption on the local area near the gate and the bed surface. The 3D model includes an inlet section before the dam and a gate outlet at the dam site, having two open boundaries in total. Among them, the inlet section before the dam corresponds to the processes of coming water and coming silting for each grid, which are determined by the calculation results of the one-dimensional water-silting model, in combination with the distribution formula of the flow velocity and the silting-content along the section; the corresponding overflow rate needs to be dynamically adjusted according to the changes of gate opening (Table 1) and the water levels of the dam site in the process of discharging water from the gates at the dam site. The 3D water-silting simulation is used to calculate difference values between the silting amount at the inlet and the silting amount at the outlet corresponding to three gate opening-closing plans, as well as changes of bed topography. According to the calculation results of the 3D model, the difference values between the silting amount at the inlet and the silting amount at the outlet corresponding Plans 1-3 are−0.51,−0.56 and−0.37 thousand tons, respectively. Therefore, the gate opening-closing plan designed in Plan 2 is the optimal gate timing plan.

Based on the above steps, in the technical solution provided in the present invention, an into-reservoir flow rate and a silting-content at the inlet of the reservoir in a preset time-length in future are collected to form a curve relation that varies with time, respectively, so as to give an into-reservoir water-silting variation curve. Then, the into-reservoir water-silting variation curve is used to perform one-dimensional water-silting movement simulation, so as to calculate a water-silting variation curve at the position before the dam (that is, a relation of a flow rate, a silting-content and a flow velocity at any position of the preset section before the dam varying with time). Since the one-dimensional water-silting simulation has high computational efficiency and few requirements for data, and the scope of the entire reservoir area is large, the one-dimensional water-silting simulation (that is, only make a calculation on a temporal variation process of water and silting in a flow direction) is used to give a preliminary ante-dam water-silting variation curve. Then, a river width and a water depth as two-dimension parameters are introduced into the ante-dam water-silting variation curve and refined, so as to give a 3D ante-dam water-sifting variation curve in any width and water depth direction of the preset section in different time-lengths, thereby improve the accuracy of the variation curve. Then, a 3D water-silting movement model is established by using the refined ante-dam water-sifting variation curve, so as to simulate water-silting movement in line of different gate opening plans, then record the situations about silting reduction before the dam corresponding to different gate opening plans, thus select a gate opening plan involving least silting before the dam or most desilting reduction before the dam from the plurality of preset gate opening plans. In this way, the optimized gate timing tactic enables silting reduction before the dam to improve.

Although examples of the present invention are described in combination with the drawings, a person skilled in the art may make various modifications and variants without departing from the essence and scope of the invention, and such modifications and variants fall within the scope defined by the claims.

What is claimed is:

1. A method of timing a reservoir gate for silting reduction before a dam, comprising the steps of
giving an into-reservoir water-silting variation curve within a preset time-length in future, the into-reservoir water-silting variation curve including an into-reservoir flow-rate variation curve shows that an into-reservoir flow-rate varies with time, and an into-reservoir silting-content variation curve shows that an into-reservoir silting-content varies with time;
predicting an ante-dam water-silting variation curve at a preset section position before a dam based on the into-reservoir water-silting variation curve;
using width parameters and water depth parameters of a river channel to refine the ante-dam water-silting variation curve; and
performing simulation on a 3D water-silting movement process by means of the refined ante-dam water-silting variation curve and a plurality of preset gate opening plans, and based on a simulation result, selecting a gate opening plan involving least silting before the dam or most desilting reduction before the dam from the plurality of preset gate opening plans,
wherein the step of predicting an ante-dam water-silting variation curve at a preset section position before a dam based on the into-reservoir water-silting variation curve includes the sub-steps of
predicting an out-reservoir flow-rate variation curve corresponding to the into-reservoir flow-rate variation curve by means of a reservoir-managing relation, which is used to present a corresponding relation between an into-reservoir flow and an out-reservoir flow at any moments;
calculating a reservoir-area water-level variation curve based on the into-reservoir flow-rate variation curve and the out-reservoir flow-rate variation curve and in combination with a water level-reservoir capacity variation relation;
inputting the into-reservoir flow-rate variation curve, the into-reservoir silting-content variation and the reservoir-area water-level variation curve into a preset one-dimensional water-silting movement model to calculate out an ante-dam flow-rate variation curve, an ante-dam water-level variation curve and an ante-dam silting-content variation curve at a preset position before the dam;
calculating an ante-dam average flow velocity variation curve based on the ante-dam flow-rate variation curve and the ante-dam water-level variation curve; and
using the ante-dam average flow velocity variation curve and the ante-dam silting-content variation curve as the ante-dam water-silting variation curve.

2. The method of timing a reservoir gate for silting reduction before a dam according to claim 1, wherein the sub-step of predicting an out-reservoir flow-rate variation curve corresponding to the into-reservoir flow-rate variation curve by means of a reservoir-managing relation comprises:
inputting a corresponding into-reservoir flow-rate value of the into-reservoir flow-rate variation curve at each moment into the reservoir-managing relation to give a corresponding out-reservoir flow-rate value at each moment, and drawing and generating the out-reservoir flow-rate variation curve based on the corresponding out-reservoir flow-rate values at each moment;
the reservoir-managing relation is that:
before the into-reservoir flow-rate value rises to a flood peak, when the into-reservoir flow-rate value is less than a first preset threshold, the out-reservoir flow-rate value is equal to the into-reservoir flow-rate value; when the into-reservoir flow-rate value is not less than a first preset threshold, the out-reservoir flow-rate value is equal to the first preset threshold;
after the into-reservoir flow-rate value starts to drop from a flood peak, when the into-reservoir flow-rate value is greater than a second preset threshold, the out-reservoir flow-rate value is equal to the into-reservoir flow-rate value; when the into-reservoir flow-rate value is not greater than a second preset threshold, the out-reservoir flow-rate value is equal to the second preset threshold.

3. The method of timing a reservoir gate for silting reduction before a dam according to claim 1, wherein the sub-step of calculating a reservoir-area water-level variation curve based on the into-reservoir flow-rate variation curve and the out-reservoir flow-rate variation curve and in combination with a water level-reservoir capacity variation relation comprises:
obtaining the water level-reservoir capacity variation relation;
calculating a reservoir capacity variation curve based on the into-reservoir flow-rate variation curve and the out-reservoir flow-rate variation curve; and
inputting the reservoir capacity variation curve into the water level-reservoir capacity variation relation to calculate the reservoir-area water-level variation.

4. The method of timing a reservoir gate for silting reduction before a dam according to claim 1, wherein the step of using width parameters and water depth parameters of a river channel to refine the ante-dam water-silting variation curve comprises:
obtaining the width parameters and the water depth parameters based on topography of the preset section position before the dam and the ante-dam water-level variation curve;
in the case of keeping a flow velocity unchanged in a river width or water depth direction, performing differentiation on the width parameters or the water depth parameters based on the ante-dam average flow velocity variation curve to calculate an ante-dam average flow velocity variation curve corresponding to each water depth or an ante-dam average flow velocity variation curve corresponding to each river width; and
in the case of keeping a silting-content unchanged in a river width or water depth direction, performing differentiation on the width parameters or the water depth parameters based on the ante-dam silting-content variation curve to calculate an ante-dam silting-content variation curve corresponding to each water depth or an ante-dam silting-content variation curve corresponding to each river width.

5. The method of timing a reservoir gate for silting reduction before a dam according to claim 1, wherein a step of generating the plurality of preset gate opening plans comprises:
determining a position of an opened gate based on a height of a reservoir bed surface; and
creating an opening plan of a gate corresponding to the position, so that the out-reservoir flow rate is equal to a sum of a total discharge flow rate and a full flow rate of a generator generating electric power at full capacity, and conforms to the reservoir-managing relation.

6. The method of timing a reservoir gate for silting reduction before a dam according to claim 1, wherein the step of performing simulation on a 3D water-silting movement process by means of the refined ante-dam water-silting variation curve and a plurality of preset gate opening plans, and based on a simulation result, selecting a gate opening plan involving least silting before the dam or most desilting reduction before the dam from the plurality of preset gate opening plans, comprises:
obtaining a 3D model from the preset section position before the dam to a dam site and dividing the 3D model into grids;
inputting the refined ante-dam water-silting variation curve into the 3D model divided into grids to give a 3D water-silting movement model;
using the 3D water-silting movement model to ergodically simulate each preset gate opening plan, and recording a silting-volume inlet-outlet difference value corresponding to each preset gate opening plan; and
using a gate opening plan having a minimum silting-volume inlet-outlet difference value as the gate opening plan involving least silting before the dam or most desilting reduction before the dam.
